(19) United States
(12) Patent Application Publication
(10) Pub. No.: US 2018/0337311 A1
(43) Pub. Date: Nov. 22, 2018

(54) ACTIVE BLUE LIGHT LEAKAGE PREVENTING LED STRUCTURES

(71) Applicant: NATIONAL CENTRAL UNIVERSITY, Taoyuan (TW)

(72) Inventors: Ching-Cherng SUN, Taoyuan (TW); Tsung-Hsun YANG, Taoyuan (TW)

(73) Assignee: National Central University

(21) Appl. No.: 15/980,166

(22) Filed: May 15, 2018

Related U.S. Application Data
(63) Continuation-in-part of application No. 15/167,455, filed on May 27, 2016, now abandoned.

(30) Foreign Application Priority Data
Mar. 8, 2016 (TW) TW105107096

(51) Int. Cl. H01L 33/50; H01L 25/16; F21K 9/64; H01L 33/08; G02B 27/09; H05B 37/02

(52) U.S. Cl. CPC H01L 33/50; H01L 25/167; H05B 37/0227; H01L 33/08; G02B 27/0955; F21K 9/64

(57) ABSTRACT

The present invention discloses active blue light leakage preventing LED structures. Each of the structure includes a circuit board, at least one blue light LED die, a photo detector/thermal sensor and a wavelength transformation layer, wherein the electric circuit on the circuit board receives detection signal from the photo detector/thermal sensor and turns off the said blue light LED die accordingly. With the implementation of the present invention, the active blue light leakage preventing LED structure turns off the blue light LED die when it reaches its usage life span limit thus avoiding damage to human from the massive release of blue light.

### BACKGROUND OF THE INVENTION

### 1. Technical Field

The present invention relates to LED structures and, more particularly, to active blue light leakage preventing LED structures.

### 2. Description of Related Art

The earth is more and more consumed and damaged by people when the progress of living keeps advancing. Hence comes the need for the everlasting existence of the earth with the increasing demands for energy saving and environmental protection solution. Out of those demands, light-emitting diodes (LEDs) advantageously feature small physical volume, high brightness, low power consumption, and ease of use and replacement and become the most rapidly growing application.

Wherein the life span or life limit of LED, known as L70, is commonly defined as the light emitted by a LED reduces to about 70% of its stable emission value. However, in actual applications, the luminous efficiency of most white light LEDs will reduce even before L70 is reached due to the heat generated that the absorption and transformation of the fluorescent material decrease accordingly. The reduction in luminous efficiency then generates more heat. With such cycling mutual effect of heat and efficiency reduction keep going on and on, massive blue light is then inevitably leaked.

On the other hand, with the increasing usage of LEDs, more and more researches and papers about the destructive effect of blue light to human eyes are published to warn that irreversible damages will occur while human eyes are exposed to blue light for more than certain amount or for certain duration.

In view of the above, it has been a common goal and progress of the LED industries and the lighting industries to create a practical, effective and easy-to-use lighting LED structure that can rapidly, accurately and actively detect abnormal status and turn off the white light LED before massive heat is generated and great amount of blue light is emitted, and thus the protection of human eyes and life quality are thus desirably achieved, while at the same time informing the user the need of replacement of lighting device.

### SUMMARY OF THE INVENTION

The present invention discloses active blue light leakage preventing LED structures. Each of the structure includes a circuit board, at least one blue light LED die, a photo detector and a wavelength transformation layer, wherein the electric circuit on the circuit board receives detection signal from the photo detector and turns off the said at least one blue light LED accordingly. With the implementation of the present invention, the active blue light leakage preventing LED structure turns off the white light LED when it reaches its usage life span limit thus avoiding the damage to human from the massive release of blue light.

The present invention provides an active blue light leakage preventing LED structure, comprising: a circuit board, comprising an upper surface; at least one blue light LED die, provided on the said upper surface and electrically connected to the said circuit board; a photo detector, provided on the said upper surface and electrically connected to the said circuit board, detecting a back scattering light of a wavelength transformation layer which results from the said blue light LED die and generating a detection signal; and a wavelength transformation layer, provided on the said upper surface, covering the said blue light LED die and the said photo detector; wherein the circuit of the said circuit board detects the said detection signal and turns off the said blue light LED die accordingly.

The present invention further provides an active blue light leakage preventing LED structure, comprising: a circuit board, comprising an upper surface; at least one blue light LED die, provided on the said upper surface and electrically connected to the said circuit board; a photo detector, provided on the said upper surface and electrically connected to the said circuit board, detecting a back scattering light of a wavelength transformation layer which results from the said blue light LED die and generating a detection signal; and a wavelength transformation layer, provided and covering a light emitting surface of the said blue light LED die; wherein the circuit of the said circuit board detects the said detection signal and turns off the said blue light LED die accordingly.

Implementation of the present invention at least involves the following inventive steps:
1. The need of complicated process or complicated equipment is not required, thus reduces implementation cost.
2. Capable of turning off the blue light LED die in time to prevent massive leakage of blue light to endanger an user.
3. Actively turn off blue light LED die to inform the user the need of replacement of lighting device, enables applications of smart controls.

The features and advantages of the present invention are detailed hereinafter with reference to the preferred embodiments. The detailed description is intended to enable a person skilled in the art to gain insight into the technical contents disclosed herein and implement the present invention accordingly. In particular, a person skilled in the art can easily understand the objects and advantages of the present invention by referring to the disclosure of the specification, the claims, and the accompanying drawings.

### BRIEF DESCRIPTION OF THE DRAWINGS

FIG. 1 is a sectional plan view of the active blue light leakage preventing LED structure according to an embodiment of the present invention;

FIG. 2 is a sectional plan view of the active blue light leakage preventing LED structure according to another embodiment of the present invention;

FIG. 3 is a sectional plan view of the active blue light leakage preventing LED structure according to the embodiment of FIG. 1 further comprises a packaging lens;

FIG. 4 is a sectional plan view of the active blue light leakage preventing LED structure according to the embodiment of FIG. 2 further comprises a packaging lens;

FIG. 5A is a sectional view of the active blue light leakage preventing LED structure according to another embodiment of the present invention, wherein the active blue light leakage preventing LED structure includes a controller;

FIG. 5B is a sectional view showing another configuration of the active blue light leakage preventing LED structure according to the embodiment of FIG. 5A;

FIG. 5C shows the active blue light leakage preventing LED structure in FIG. 5A further including a packaging lens;

FIG. 5D shows the active blue light leakage preventing LED structure in FIG. 5B further including a packaging lens;

FIG. 5E shows the circuit diagram of the active blue light leakage preventing LED structure in one of FIG. 5A to FIG. 5D;

FIG. 6 shows a set of characteristic curves for the wavelength conversion layer and the blue light leakage value;

FIG. 7A shows a set of characteristic curves for the blue light leakage value and the power supply;

FIG. 7B shows another set of characteristic curves for the blue light leakage value and the power supply;

FIG. 8A is a sectional view of the active blue light leakage preventing LED structure according to yet another embodiment of the present invention, wherein the active blue light leakage preventing LED structure includes a thermal sensor;

FIG. 8B is a sectional view showing another configuration of the active blue light leakage preventing LED structure according to the embodiment of FIG. 8A;

FIG. 8C shows the active blue light leakage preventing LED structure in FIG. 8A further including a packaging lens;

FIG. 8D shows the active blue light leakage preventing LED structure in FIG. 8B further including a packaging lens;

FIG. 8E shows the circuit diagram of the active blue light leakage preventing LED structure in one of FIG. 8A to FIG. 8D;

FIG. 9A shows a circuit diagram in which a thermistor is used as the thermal sensor;

FIG. 9B shows a set of characteristic curves for the power supply and for temperature variation serving as the operation logic of the circuit in FIG. 9A;

FIG. 10A shows a circuit diagram in which a thermistor is used as the thermal sensor and which also includes a switch; and

FIG. 10B shows a set of characteristic curves for the power supply and for temperature variation serving as the operation logic of the circuit in FIG. 10A.

### DETAILED DESCRIPTION OF THE INVENTION

### First Embodiment

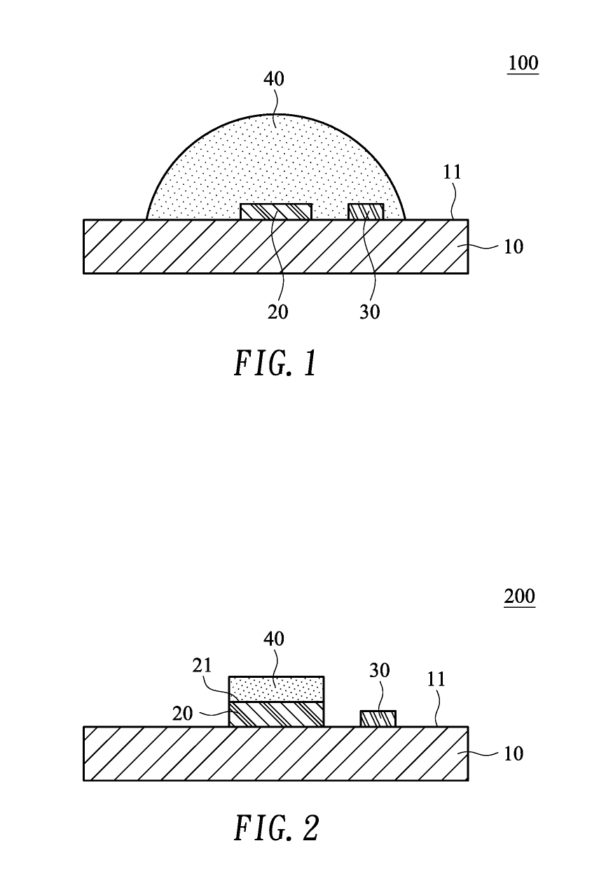

Please refer to FIG. 1, an active blue light leakage preventing LED structure 100 according to an embodiment of the present invention includes a circuit board 10, at least one blue light LED die 20, a photo detector 30, and a wavelength transformation layer 40.

As shown in FIG. 1, the circuit board 10 of the active blue light leakage preventing LED structure 100 comprises an upper surface 11, and the circuit board 10 can be a FRP, ceramic, or flexible circuit board that contains at least one set of circuit path.

As also shown in FIG. 1, at least one blue light LED die 20 is provided on an upper surface 11 of the circuit board 10 and is electrically connected to the circuit board 10. The number or size or even the specification or grade of the said blue light LED die 20 that emits blue light can be chosen as required in actual applications.

Referring again to FIG. 1, the photo detector 30 is also provided on the upper surface 11 of the circuit board 10 and is electrically connected to the circuit board 10. In the embodiment, the photo detector 30 is to detect a back scattering light of a wavelength transformation layer 40 which results from the said blue light LED die 20 and then generates a detection signal for control usage. Wherein the circuit board 10 or at least one set of circuit path of the circuit board 10 receives the detection signal generated from the photo detector 30 and turns off the blue light LED die 20 accordingly.

With continued reference to FIG. 1, the wavelength transformation layer 40, which is provided and set also on the upper surface 11 of the circuit board 10, covers the blue light LED die 20 and the photo detector 30. The said wavelength transformation layer 40 can be a phosphor powder layer, a quantum dot layer, or any material layer formed with photoluminescence material.

Further, the phosphor powder layer used as the wavelength transformation layer 40 can be a yellow color phosphor powder layer, a red-green mixed color phosphor powder layer, or an orange-green mixed color phosphor powder layer.

The aforesaid back scattering light received by the photo detector 30 is a portion of the blue light emitted by the blue light LED die 20 and reflected by the wavelength transformation layer 40 toward the photo detector 30. When the detected back scattering light reduces to a value below a predetermined threshold after a period of time of usage, the active blue light leakage preventing LED structure 100 is about to radiate large amount of blue light, wherein the temperature of the wavelength transformation layer 40 is greatly raised thus reduces enormously the light mixing function to leak massive quantity of blue light.

With the implementation of the photo detector 30 on the upper surface 11 of the circuit board 10, the back scattering light inside the active blue light leakage preventing LED structure 100 can always be detected, thus, the photo detector 30 actively generates a detection signal for the electrical circuit on the circuit board 10 to turn off the blue light LED die 20 accordingly, preventing unnecessary damage to users.

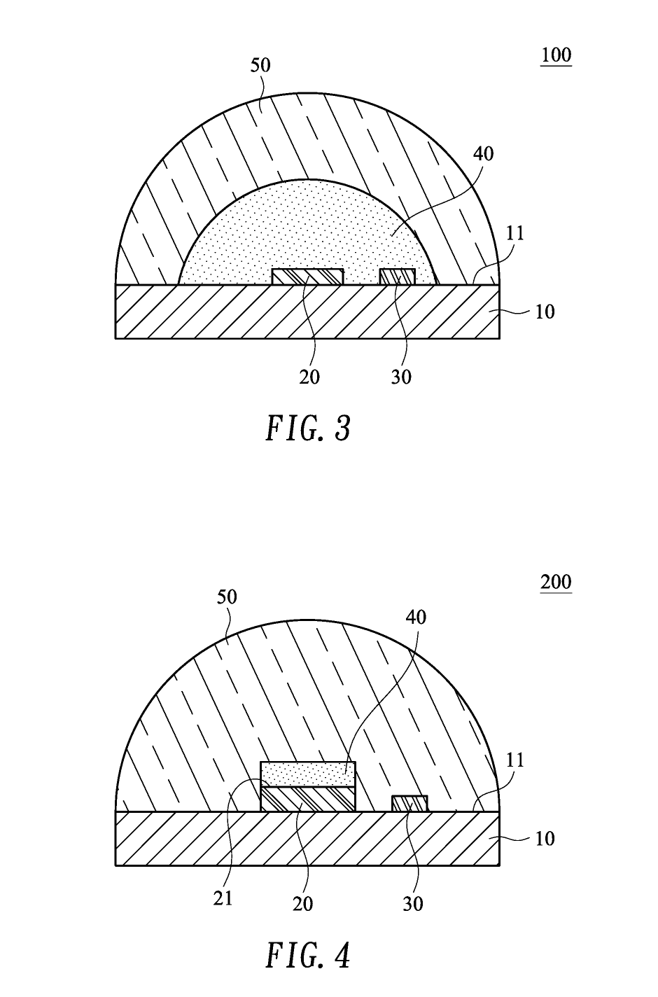

As shown in FIG. 3, the active blue light leakage preventing LED structure 100 further comprises a packaging lens 50, provided and featured on the upper surface 11 of the circuit board 10 to cover the wavelength transformation layer 40, the photo detector 30, and the blue light LED die 20.

Wherein the said packaging lens 50 or the said wavelength transformation layer 40 can be glued on the upper surface 11 of the circuit board 10 with a gasket.

Please refer to FIG. 2, an active blue light leakage preventing LED structure 200 according to another embodiment of the present invention includes a circuit board 10, at least one blue light LED die 20, a photo detector 30, and a wavelength transformation layer 40.

As shown in FIG. 2, the wavelength transformation layer 40 of the embodiment covers only the light emitting surface 21 of the blue light LED die 20.

In this embodiment, the features and the relationships of the circuit board 10, the blue light LED die 20 and the photo detector 30 of the active blue light leakage preventing LED structure 200 are the same as in the embodiment of the active blue light leakage preventing LED structure 100 that requires no further descriptions.

As shown in FIG. 4, the active blue light leakage preventing LED structure 200 further comprises a packaging lens 50, provided and fixed on the upper surface 11 of the circuit board 10 to cover the wavelength transformation layer 40, the photo detector 30, and the blue light LED die 20.

As can be seen in FIG. 3 and FIG. 4, the implementation of the packaging lens 50 not only protects the wavelength transformation layer 40, the photo detector 30, and the blue light LED die 20 covered, also the beam shape, the focus point, the beam size or the beam divergence angle of the active blue light leakage preventing LED structure 100 or the active blue light leakage preventing LED structure 200 can be achieved by choosing different shape or function of the packaging lens 50.

Moreover, with the implementation of the photo detector 30 on the upper surface 11 of the circuit board 10, the active blue light leakage preventing LED structure 200 is also capable of detecting the back scattering light of the wavelength transformation layer which results from the blue light LED die 20 inside. When the blue light LED die 20 reaches its usage life span limit, the detected back scattering blue light reduces to a value below a predetermined threshold after a period of time of usage and the active blue light leakage preventing LED structure 100 is about to radiate large amount of blue light, wherein the temperature of the wavelength transformation layer 40 is greatly raised thus reduces enormously the light mixing function to leak massive quantity of blue light, the photo detector 30 actively generates a detection signal for the electrical circuit on the circuit board 10 to turn off the blue light LED die 20 accordingly, thus preventing unnecessary damage to an user.

### Second Embodiment

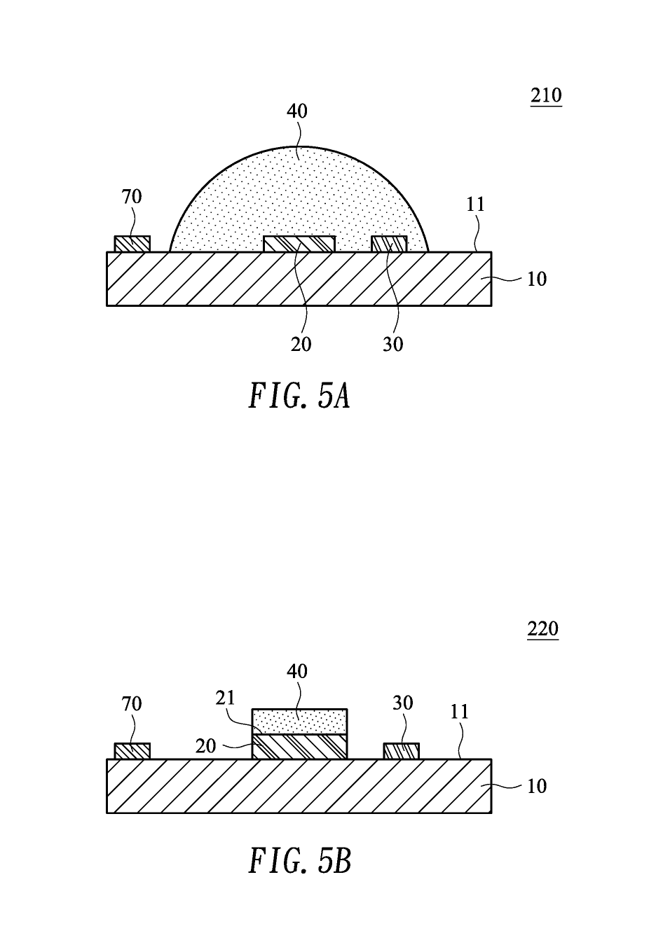

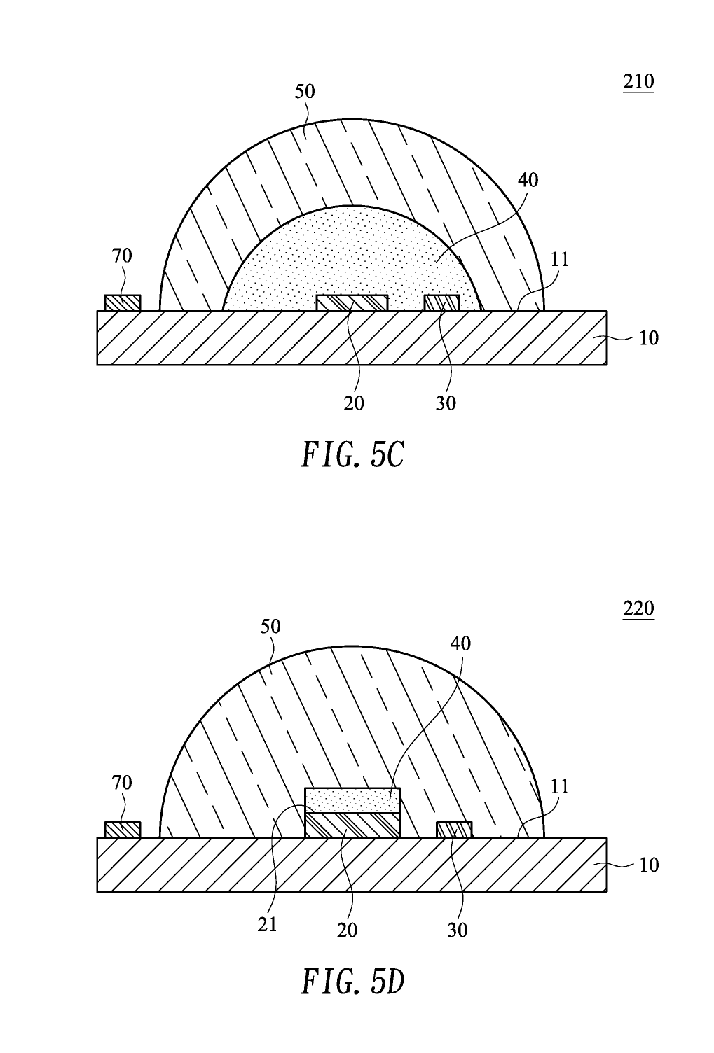

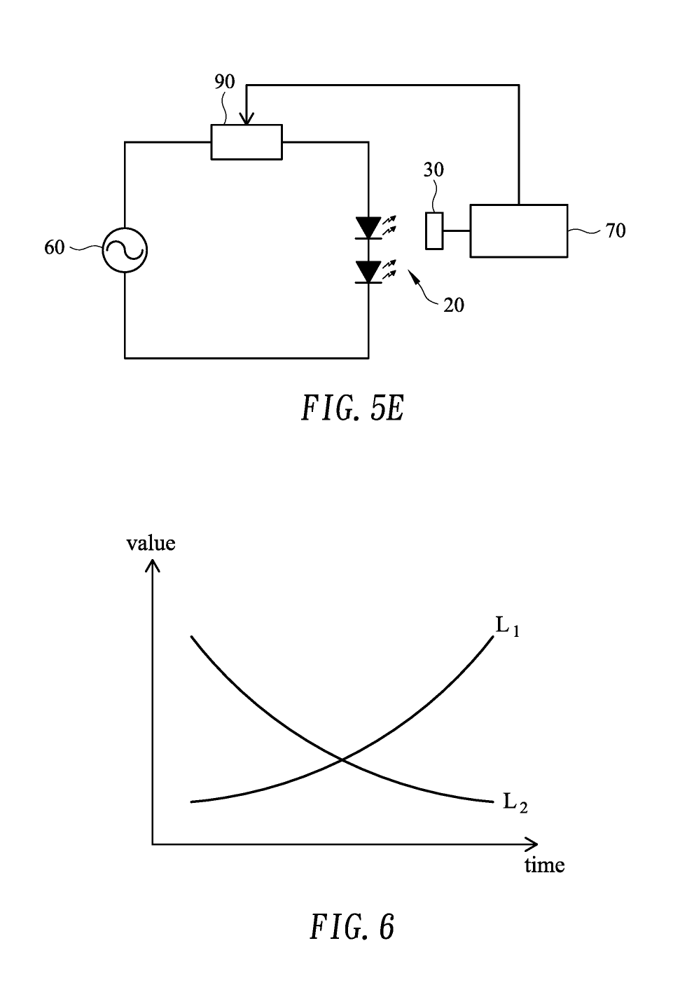

Referring to FIG. 5A to FIG. 5E, the first embodiment described above can be reconfigured into an active blue light leakage preventing LED structure 210 that includes a circuit board 10, at least one blue LED die 20 (hereinafter referred to as the blue LED die 20 for short, although a plurality of blue LED dies 20 are also feasible, as shown in FIG. 5E, in which two blue LED dies 20 are provided), a wavelength conversion layer 40, a power source 60, a photodetector 30, and a controller 70.

The active blue light leakage preventing LED structure 210 according to this embodiment may further include a packaging lens 50, wherein the packaging lens 50 is fixedly provided on the upper surface of the circuit board 10 and covers the wavelength conversion layer 40, the blue LED die 20, and the photodetector 30 to form a complete LED package structure.

Referring to FIG. 6, the value axis represents the degree of aging of the wavelength conversion layer 40 when corresponding to the curve L1. The curve L1, therefore, shows that the wavelength conversion layer 40 gradually ages as its service time increases. When corresponding to the curve L2, the same value axis represents values of backscattering light instead. It can be known from the curve L2 that, as the degree of aging of the wavelength conversion layer 40 increases, the blue light leakage value of the blue LED die 20 increases too, but the yellow or blue light value of backscattering light decreases.

In this embodiment, the foregoing characteristic curves are used to solve the problem of excessive blue light leakage caused by the aging of the wavelength conversion layer 40. More specifically, active blue light leakage prevention can be achieved by detecting the blue light leakage value dynamically and controlling the electric power supplied to the blue LED die 20 accordingly.

The definitions, structural details, functions, and connecting relationships of the circuit board 10, the blue LED die 20, and the wavelength conversion layer 40 are identical to those disclosed for the first embodiment and therefore will not be stated repeatedly.

The power source 60 is electrically connected to the blue LED die 20 through a switch 90 and serves mainly to provide the electric power needed by the blue LED die 20 during operation.

The photodetector 30 is fixedly provided on the upper surface of the circuit board 10 and is electrically connected to the circuit board 10. The photodetector 30 serves mainly to detect the backscattering light value of the light generated by the wavelength conversion layer 40 reacting with the light emitted by the blue LED die 20. The photodetector 30 dynamically generates a detection signal that includes the backscattering light value.

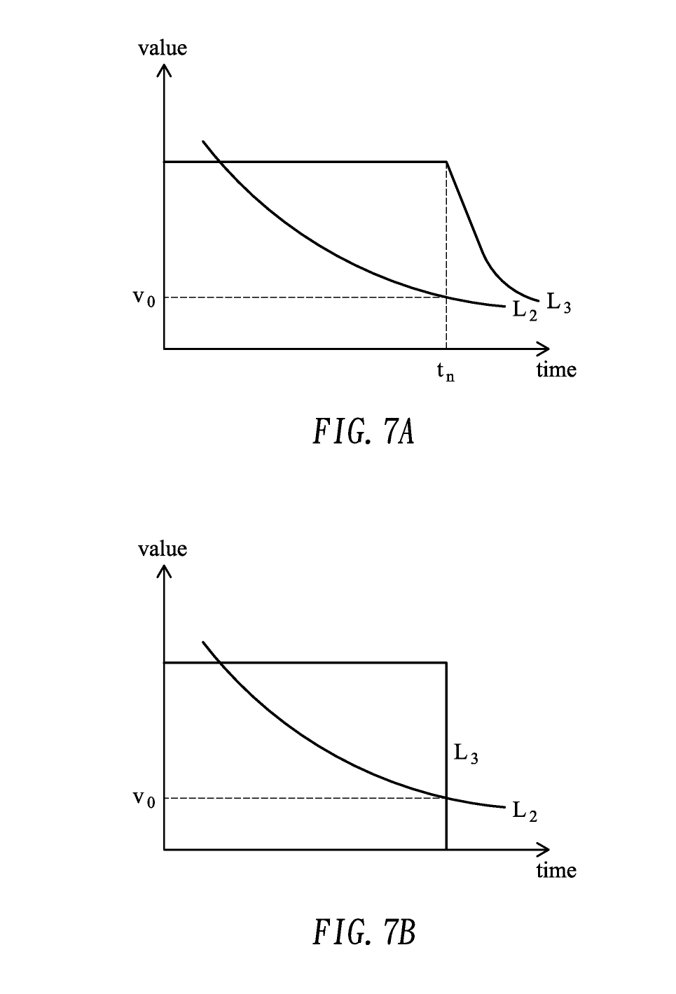

Referring to FIG. 7A and FIG. 7B, the value axes when corresponding respectively to the curves L3 represent electric power output by the power source. The initial phase of each curve L3 indicates that constant electric power is supplied. When each curve L2 reaches V0, which is a predetermined value set according to the characteristic curve L2 itself as the threshold for activating the controller 70, the controller 70 begins to control the switch 90 according to the corresponding characteristic curve L3 in order to reduce or turn off power supply from the power source 60, thereby preventing the blue light of the blue LED die 20 from leaking out.

In FIG. 7A, the controller 70 controls the power source 60 in an analog and decreasing manner. For example, when the backscattering light value detected by the photodetector 30 arrives at the predetermined value V0, the controller 70 reduces the electricity output of the power source 60 according to the curve L3 in an analog manner to prevent the blue light of the blue LED die 20 from leaking out.

In FIG. 7B, the controller 70 controls the power source 60 digitally according to the curve L3. For example, when the backscattering light value detected by the photodetector 30 reaches the predetermined value V0, the controller 70 turns off the power source 60 directly by controlling the switch 90, in order to prevent the blue light of the blue LED die 20 from leaking out.

### Third Embodiment

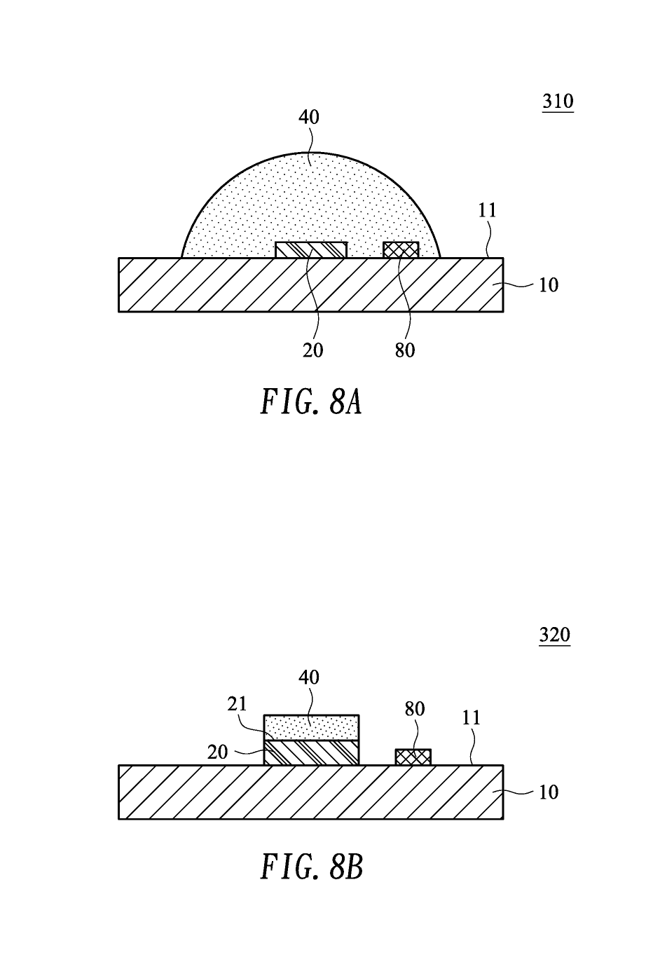

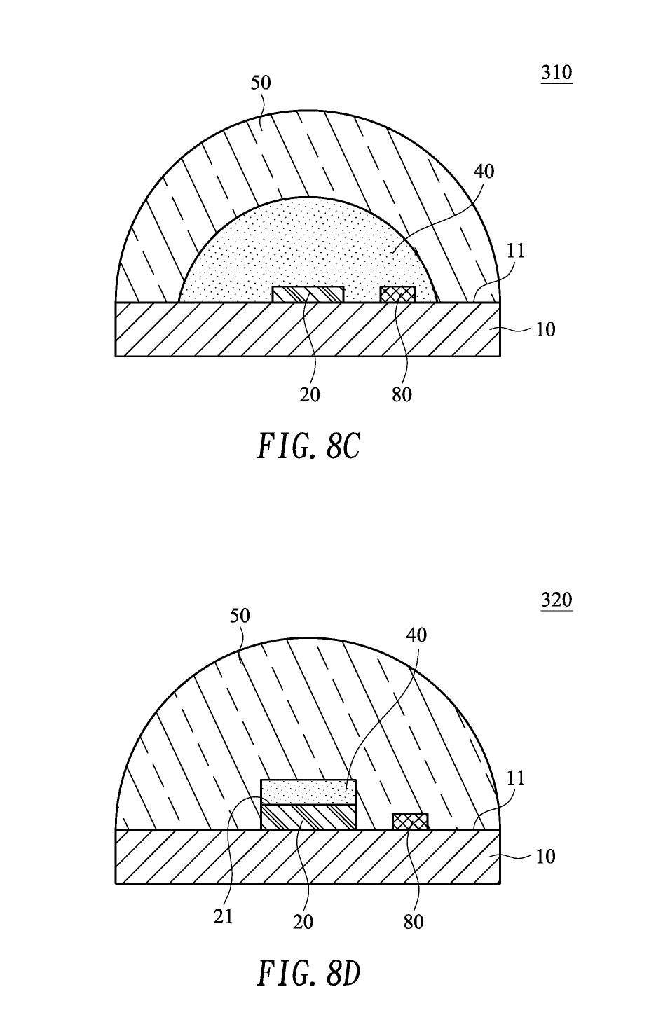

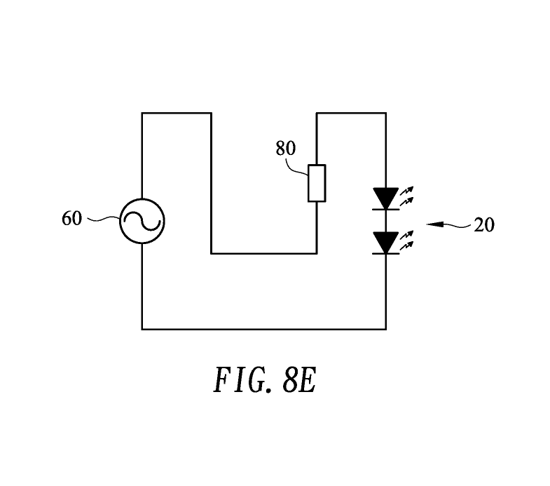

Referring to FIG. 8A to FIG. 8E, the active blue light leakage preventing LED structures 310 and 320 according to this embodiment include a circuit board 10, at least one blue LED die 20 (hereinafter referred to as the blue LED die 20 for short, although a plurality of blue LED dies 20 are also feasible, as shown in FIG. 8E, in which two blue LED dies 20 are provided), a wavelength conversion layer 40, a light source 60, and a thermal sensor 80.

These active blue light leakage preventing LED structures may further include a packaging lens 50 fixedly provided on the upper surface of the circuit board 10 and covering the wavelength conversion layer 40, the blue LED die 20, and the thermal sensor 80 to from a complete LED package structure.

The definitions, structural details, functions, and connecting relationships of the circuit board 10, the blue LED die 20, and the wavelength conversion layer 40 are identical to those disclosed for the first embodiment and therefore will not be stated repeatedly.

The power source 60 is electrically connected to the blue LED die 20 and serves mainly to provide the electric power needed by the blue LED die 20 during operation.

The thermal sensor 80 is provided adjacent to the blue LED die 20. When the temperature of the blue LED die 20 rises during operation, the wavelength conversion layer loses its intended effect gradually, and the amount of blue light leaking out increases as a result. The thermal sensor 80, therefore, is configured to reduce or turn off power supply from the power source 60 to the blue LED die 20 when detecting a rise in the temperature of the blue LED die 20, thereby preventing blue light from leaking out.

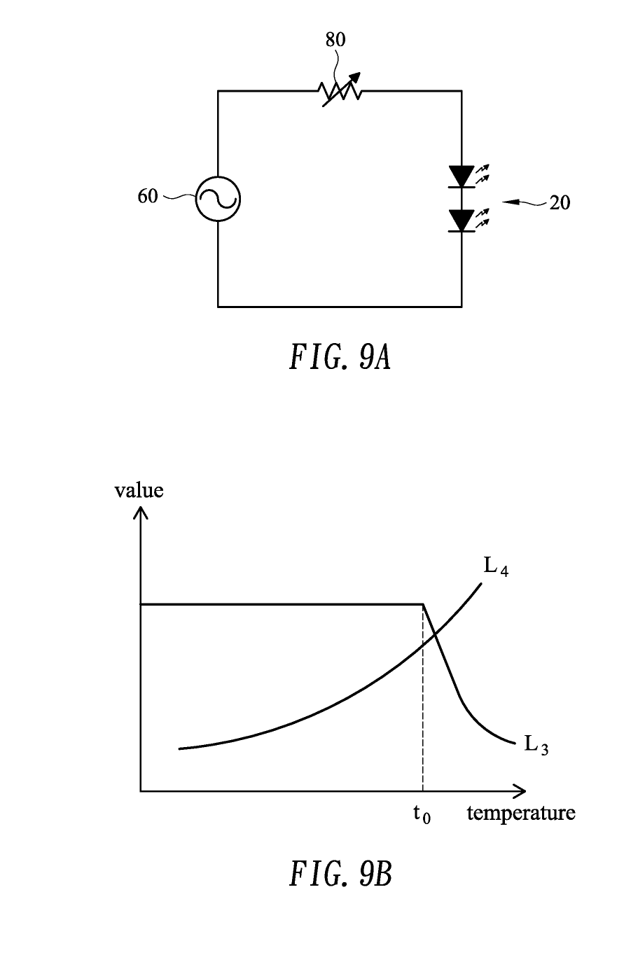

Referring to FIG. 9A and FIG. 9B, the value axis in FIG. 9B when corresponding to the curve L4 represents temperature variation detected by the thermal sensor 80. The curve L4, therefore, is a characteristic curve of the blue LED die 20 in relation to variation of its working temperature over time. The thermal sensor 80 in this embodiment is a thermistor connected in series between the blue LED die 20 and the power source 60, and the resistance of the thermistor rises with the temperature of the blue LED die 20. The thermistor can be configured to reduce power supply from the power source 60 to the blue LED die 20 according to the characteristics of the curve L3 when the temperature of the blue LED die 20 rises, thereby preventing blue light from leaking out.

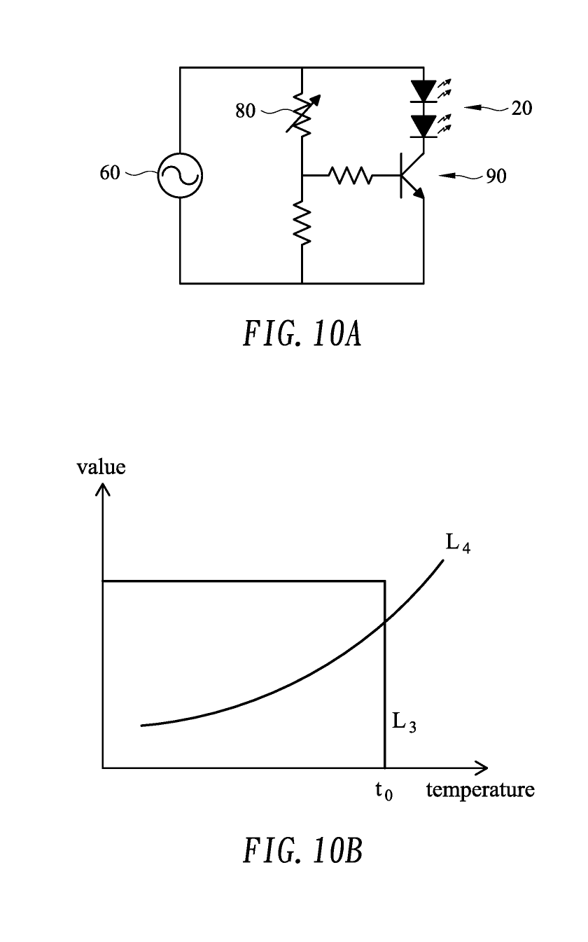

Referring to FIG. 10A and FIG. 10B, the value axis in FIG. 10B when corresponding to the curve L4 also represents temperature variation detected by the thermal sensor 80. The active blue light leakage preventing LED structure according to this embodiment may be additionally provided with a switch 90 connected in series between the blue LED die 20 and the power source 60 and use a thermistor as the thermal sensor 80 so that, when the temperature of the blue LED die 20 rises to a predetermined temperature value T0, the thermistor turns off the switch 90 directly, thus turning off power supply from the power source 60 to the blue LED die 20 according to the characteristics of the curve L3 to prevent blue light from leaking out.

The embodiments described above are intended only to demonstrate the technical concept and features of the present invention so as to enable a person skilled in the art to understand and implement the contents disclosed herein. It is understood that the disclosed embodiments are not to limit the scope of the present invention. Therefore, all equivalent changes or modifications based on the concept of the present invention should be encompassed by the appended claims.

What is claimed is:

1. An active blue light leakage preventing light-emitting diode (LED) structure, comprising:
a circuit board having an upper surface;
at least one blue LED die fixedly provided on the upper surface and electrically connected to the circuit board;
a wavelength conversion layer fixedly provided on and covering a light output surface of the blue LED die;
a power source electrically connected to the blue LED die through a switch;
a photodetector fixedly provided on the upper surface and electrically connected to the circuit board, wherein the photodetector is configured to detect a backscattering light value of the blue LED die and generate a detection signal; and
a controller for reading the detection signal and, upon determining that the backscattering light value exceeds a predetermined value, controlling the switch to reduce or turn off power supply from the power source, thereby preventing blue light of the blue LED die from leaking out.

2. The active blue light leakage preventing LED structure of claim 1, wherein the wavelength conversion layer is one of a phosphor powder layer, a quantum dot layer, and a layer formed of a photoluminescent material.

3. The active blue light leakage preventing LED structure of claim 1, wherein the wavelength conversion layer is a phosphor powder layer comprising one of yellow phosphor powder, a mixture of red phosphor powder and green phosphor powder, and a mixture of orange phosphor powder and green phosphor powder.

4. The active blue light leakage preventing LED structure of claim 1, wherein the photodetector is configured to receive backscattering light generated by the wavelength conversion layer reflecting light emitted by the blue LED die.

5. The active blue light leakage preventing LED structure of claim 1, further comprising a packaging lens, wherein the packaging lens is fixedly provided on the upper surface and covers the wavelength conversion layer, the blue LED die, and the photodetector.

6. The active blue light leakage preventing LED structure of claim 1, wherein the wavelength conversion layer is fixedly provided on the upper surface and covers the blue LED die and the photodetector.

7. The active blue light leakage preventing LED structure of claim 1, wherein the controller controls the power source by reducing power supply therefrom in an analog manner.

8. The active blue light leakage preventing LED structure of claim 1, wherein the controller controls the power source by directly turning off the power source in a digital manner.

9. An active blue light leakage preventing light-emitting diode (LED) structure, comprising:
a circuit board having an upper surface;
at least one blue LED die fixedly provided on the upper surface and electrically connected to the circuit board;
a wavelength conversion layer fixedly provided on and covering a light output surface of the blue LED die;
a power source electrically connected to the blue LED die; and
a thermal sensor provided adjacent to the blue LED die, wherein when a temperature of the blue LED die rises, the thermal sensor reduces or turns off power supply from the power source to the blue LED die to prevent blue light from leaking out.

10. The active blue light leakage preventing LED structure of claim 9, wherein the wavelength conversion layer is one of a phosphor powder layer, a quantum dot layer, and a layer formed of a photoluminescent material.

11. The active blue light leakage preventing LED structure of claim 9, wherein the wavelength conversion layer is a phosphor powder layer comprising one of yellow phosphor powder, a mixture of red phosphor powder and green phosphor powder, and a mixture of orange phosphor powder and green phosphor powder.

12. The active blue light leakage preventing LED structure of claim 9, further comprising a packaging lens, wherein the packaging lens is fixedly provided on the upper surface and covers the wavelength conversion layer, the blue LED die, and the thermal sensor.

13. The active blue light leakage preventing LED structure of claim 9, wherein the thermal sensor is a thermistor.

14. The active blue light leakage preventing LED structure of claim 13, wherein the thermistor is connected in series between the blue LED die and the power source, and when the temperature of the blue LED die rises, resistance of the thermistor increases to reduce power supply from the power source to the blue LED die, thereby preventing blue light from leaking out.

15. The active blue light leakage preventing LED structure of claim 13, further comprising a switch connected in series between the blue LED die and the power source, wherein when the temperature of the blue LED die rises to a predetermined temperature value, the thermistor turns off the switch to turn off power supply from the power source to the blue LED die, thereby preventing blue light from leaking out.
